(19) United States
(12) Patent Application Publication
(10) Pub. No.: US 2008/0303095 A1
(43) Pub. Date: Dec. 11, 2008

(54) VARYING MUGFET WIDTH TO ADJUST DEVICE CHARACTERISTICS

(76) Inventors: Weize Xiong, Austin, TX (US); Cloves Rinn Cleavelin, Dallas, TX (US)

Correspondence Address: TEXAS INSTRUMENTS INCORPORATED, P O BOX 655474, M/S 3999, DALLAS, TX, 75265, US

(21) Appl. No.: 11/759,710

(22) Filed: Jun. 7, 2007

(51) Int. Cl. H01L 29/76; H01L 21/8234

(52) U.S. Cl. 257/365; 438/283; 257/E29.226; 257/E21.616

(57) ABSTRACT

One embodiment of the present invention relates to an integrated circuit that includes a first multi-gate transistor that has a first fin width and a first threshold voltage. The integrated circuit also includes a second multi-gate transistor that has a second fin width that is greater than the first width and a second threshold voltage that is less than the first threshold voltage. Other circuits and methods are also disclosed.

### FIELD OF INVENTION

The present invention relates generally to semiconductor devices and more particularly to multi-gate transistors (MuGFETs).

### BACKGROUND OF THE INVENTION

As the performance and process limitations on scaling planar transistors are reached, attention has been recently directed to transistor designs having multiple gates (e.g., three-dimensional MOS transistors), which may also be referred to as Multi-Gate Field Effect Transistors (MuGFETs). In theory, these designs provide more control over a scaled channel by situating the gate around two or more sides of a silicon fin in which a conductive channel is formed.

By alleviating the short channel effects seen in traditional scaled planar transistors, multi-gate designs offer the prospect of improved transistor performance. This is due primarily to the ability to invert a larger portion of the channel silicon because the gate extends on more than one side of the channel. In practice, however, the conventional multi-gate approaches have suffered from cost and performance shortcomings.

Accordingly, to realize the advantages of scaling while overcoming the shortcomings of traditional multi-gate transistors, there remains a need for improved multi-gate transistors and manufacturing techniques.

### SUMMARY OF THE INVENTION

The following presents a simplified summary in order to provide a basic understanding of one or more aspects of the invention. This summary presents one or more concepts of the invention in a simplified form as a prelude to the more detailed description that is presented later and is not an extensive overview of the invention. In this regard, the summary is not intended to identify key or critical elements of the invention, nor does the summary delineate the scope of the invention.

One embodiment of the present invention relates to an integrated circuit that includes a first multi-gate transistor that has a first fin width and a first threshold voltage. The integrated circuit also includes a second multi-gate transistor that has a second fin width that is greater than the first width and a second threshold voltage that is less than the first threshold voltage.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIGS. 1A-1B show embodiments of a first MuGFET and a second MuGFET;

FIG. 2 shows a plot of threshold voltage vs. fin width;

FIGS. 3A-3C show another embodiment of a relatively narrow MuGFET;

FIGS. 4A-4C show another embodiment of a relatively wide MuGFET;

FIGS. 5A-5B show embodiments of enhancement/depletion mode MuGFETs;

FIG. 6 shows an I-V curve for an enhancement/depletion mode MuGFET; and

FIGS. 7A-7B show embodiments of an accumulation mode MuGFET.

### DETAILED DESCRIPTION OF THE INVENTION

The present invention will now be described with reference to the attached drawing figures, wherein like reference numerals are used to refer to like elements throughout, and wherein the illustrated structures and devices are not necessarily drawn to scale.

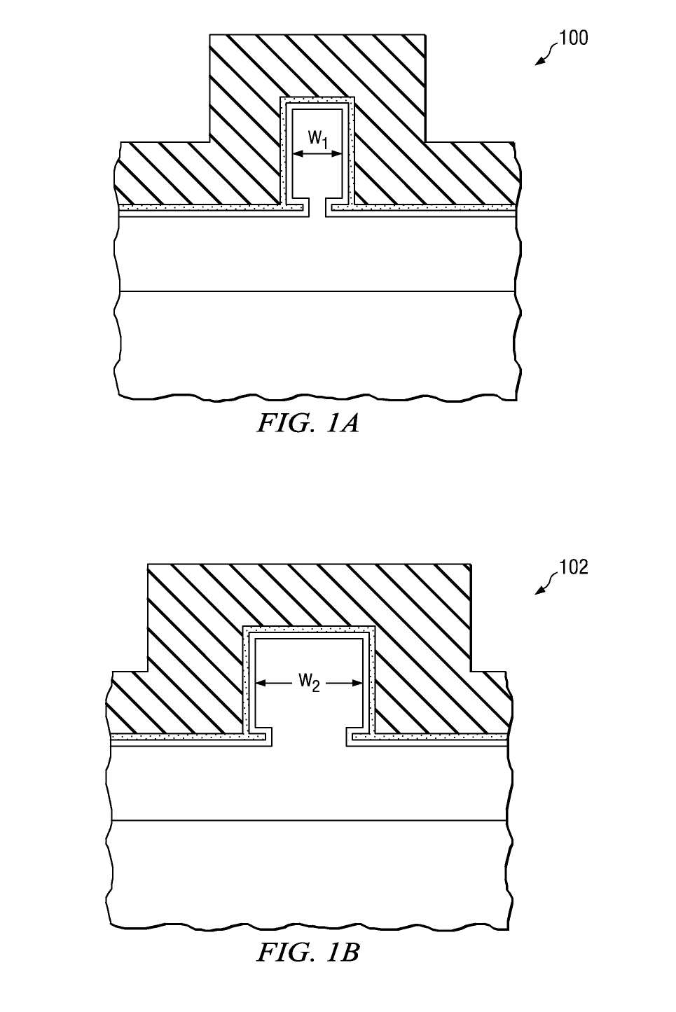

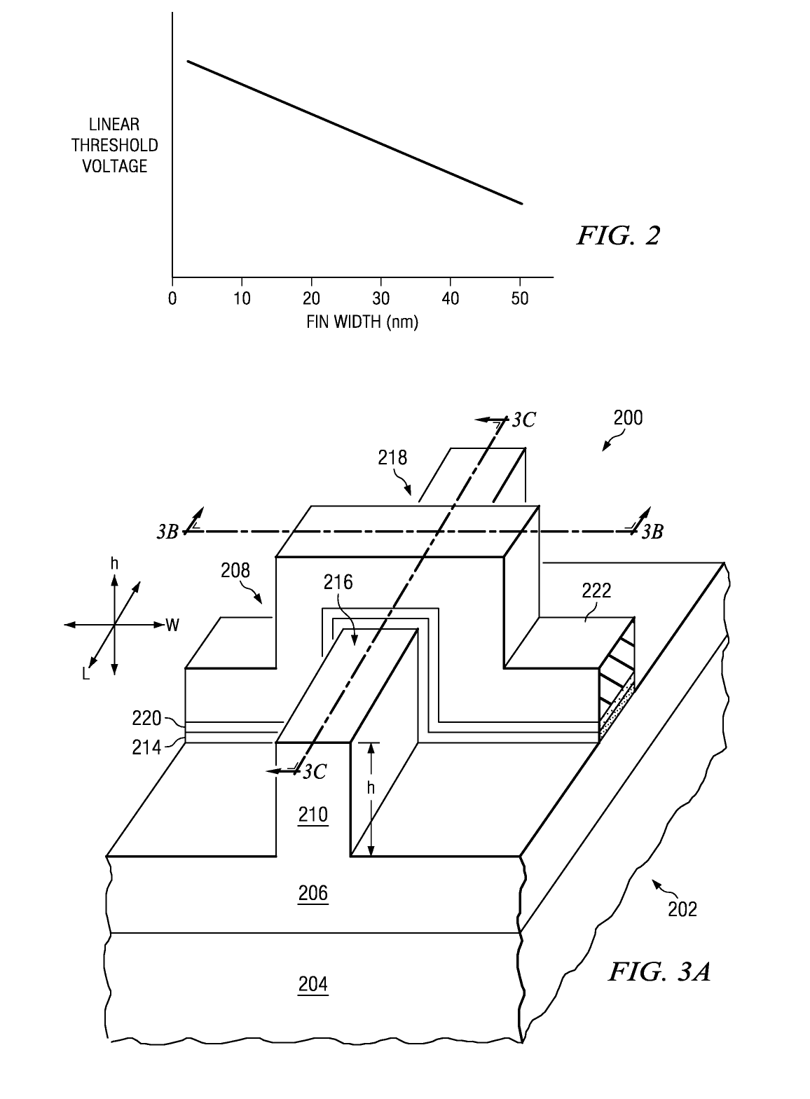

One concept of the invention allows a designer to tailor a MuGFET's voltage threshold (V_{T}) where strong inversion occurs as a function of the MuGFET's fin width (W). Thus, an integrated circuit may be provided that has MuGFETs of varying fin widths, where MuGFETs with narrower fins have higher V_{T}'s and MuGFETs with wider fins have lower V_{T}'s. For example, FIG. 1A shows a first (relatively narrow) MuGFET 100, having fin width W₁ and voltage threshold V_{T1}, and FIG. 1B shows a second (relatively wide) MuGFET 102 having fin width W₂ and voltage threshold V_{T2}. As shown W₂>W₁, and therefore V_{T1}>V_{T2}. Other than their differing fin widths and voltage thresholds, the MuGFETs 100, 102 may have many, if not all, of the same or similar features (e.g., channel doping concentration, source/drain doping concentration, fin height, etc.), although they may also have different features. FIG. 2 shows a general trend where MuGFET V_{T} decreases as fin width increases.

While FIGS. 1A-1B show only two MuGFETs, it will be appreciated that any number of MuGFETs could be formed where various fin widths and gate lengths are used for the MuGFETs. Thus, by invoking slight changes (or drastic changes) to MuGFET width, a designer can tailor the associated V_{T} to his liking.

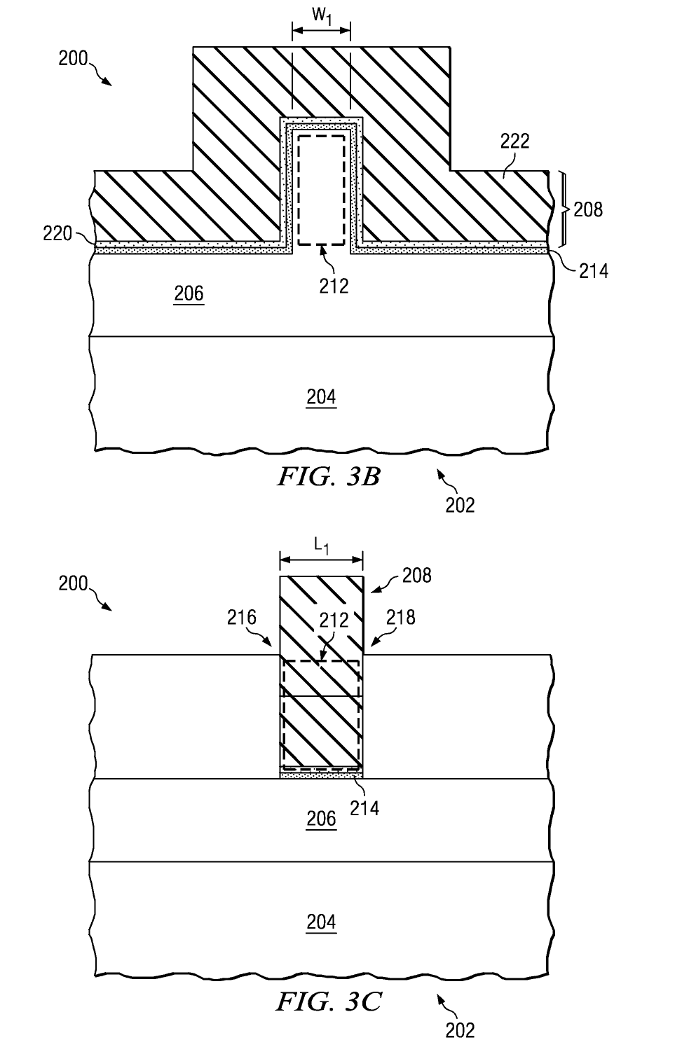

Referring now to FIGS. 3A-3C, one can see a more detailed view of a relatively narrow MuGFET 200 with width W₁. It will be appreciated that the relatively narrow MuGFET 200 is “narrow” relative to the relatively wide MuGFET 300 (and vice versa), and is not necessarily narrow relative to other industry MuGFETs. As shown, the MuGFET 200 may be formed over a semiconductor body 202 that comprises an insulator layer 204 and a semiconductor substrate layer 206. In other un-illustrated embodiments, the insulator layer 204 need not be present.

The MuGFET 200 comprises a gate electrode 208 that straddles an undoped silicon fin 210, where a channel region 212, is associated with the fin 210. A dielectric layer 214 is sandwiched between the fin 210 and the gate electrode 208, and electrically separates the fin 210 from the gate electrode 208. A source 216 and drain 218, which are typically characterized by a relatively high dopant concentration (relative to the doping in the channel region 212), are formed within the fin 210 laterally separated from one another by a gate length L₁ as measured across the channel region 212 under the gate electrode 208. In one short-channel embodiment, the fin width W₁ could be approximately half of the gate length L₁. Generally, current in the form of charged carriers (i.e., negatively charged electrons or positively charged holes) flows along the length L₁ of the device though the channel region 212.

As shown, the gate electrode 208 may comprise two layers, namely, a first gate electrode layer 220, which is typically a metal, and a second gate electrode layer 222, which is typically polysilicon. Other layers (e.g., dielectrics, vias, metal1, metal2, etc.), which are not shown for the purposes of simplicity, may also be formed over the gate electrode 208 and other surfaces.

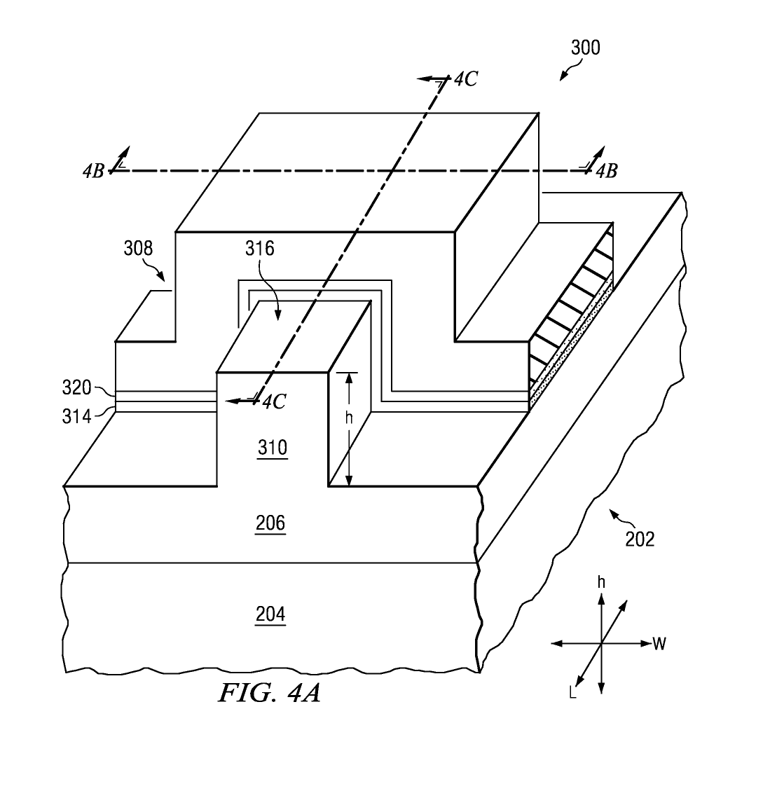

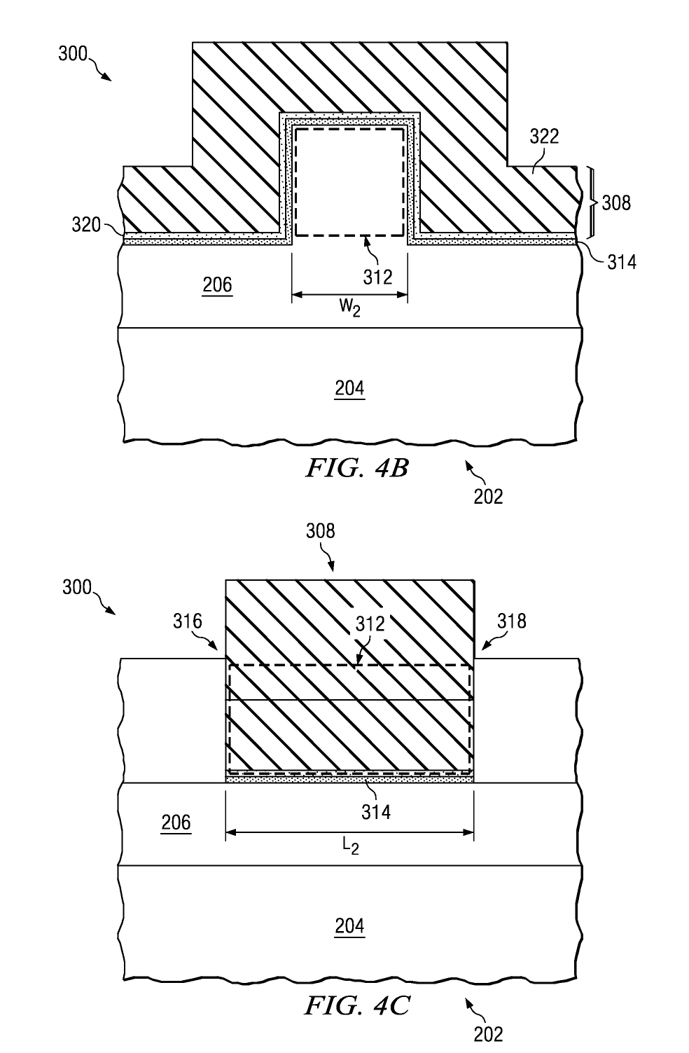

FIGS. 4A-4B show a relatively wide MuGFET 300. Generally speaking, the relatively wide MuGFET 300 may have the same or similar features as the relatively narrow MuGFET described above (e.g., height h, substrate 206, doping concentrations, etc.). In one long channel embodiment, the relatively wide MuGFET 300 could have a fin width W₂ that could be approximately one half of the gate length L₂. Long channel devices can be devices with gate lengths that are at least three times greater than the minimum gate length of a given technology node.

In one embodiment, the first gate electrode layer 220 of the relatively narrow MuGFET 200 and the first gate electrode layer 320 of the relatively wide MuGFET 300 comprise the same metal. This metal could be a mid-gap metal. Mid-gap means that the work function is about mid-way between the valence band and the conduction band of the substrate. One advantage of using a single mid-gap metal over all MuGFET devices on the integrated circuit is that it requires fewer mask steps than depositing one metal over p-type devices and another metal over n-type devices, which is another option in the manufacture of MuGFETs. However, prior solutions have suffered from a drawback in that the use of a single mid-gap metal over both p-type and n-type MuGFETs has hereforeto provided a relatively high V_{T} for the devices. Thus, by widening a MuGFET, one can reduce the V_{T} of the MuGFET to compensate for a high V_{T}, which allows multiple V_{T}'s across the integrated circuit while still retaining the benefits of using a single mid-gap metal.

Although the MuGFETs 200, 300 often have some similar features, they may also have features that are different. For example, as mentioned the MuGFETs 200, 300 differ in their respective fin widths W₁, W₂, where W₂>W₁. In addition, they can also differ in their respective gate lengths L₁, L₂. For example, the wide MuGFET 300 (FIG. 4A) can have a gate length L₂ that is at least approximately three times longer than the gate length L₁ of the narrow MuGFET 200 (FIG. 3A). This may facilitate better analog characteristics for the wide MuGFET.

During operation of the MuGFETs 200,300, a gate-source voltage (V_{GS}) may be applied to the gate electrode (e.g., 208) relative to the source (e.g., 216). This V_{GS} can alter the number of charged carriers in the channel region (e.g., 212) to facilitate desired functionality. In various embodiments, the previously described MuGFETs can be implemented as accumulation mode devices or enhancement/depletion mode devices.

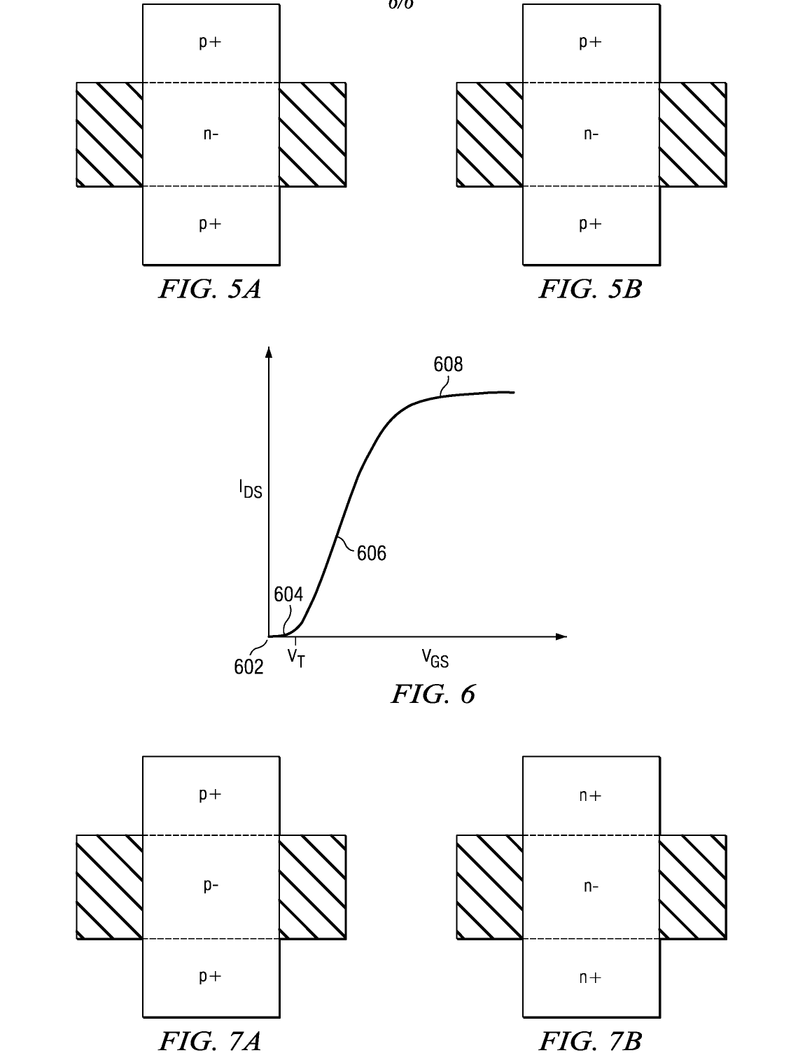

Enhancement/depletion mode devices typically have one type of dopant in the source/drain regions (e.g., 216/218) and an opposite type of dopant in the channel region (e.g., 212). For example, FIG. 5A shows a top level view of one enhancement mode PMOS device (with the gate dielectric cut away) that has a source/channel/drain dopant scheme of P+/N−/P+, while FIG. 5B shows similar view for an enhancement mode NMOS device that has a source/channel/drain dopant scheme of N+/P−/N+. In various implementations, enhancement mode MuGFETs typically operate in one of four conduction regions shown in FIG. 6, namely: off 602, sub-threshold 604, linear 606, and saturation 608. In the off state 602, V_{GS}=0 and any would-be carriers in the channel region are bound to the lattice (i.e., there no mobile carriers in the channel). Therefore, even if a voltage is applied between the source and drain (V_{DS}), no current will flow in the off state below breakdown. In the sub-threshold region 604 (where |V_{GS}|<|V_{T}|), a few carriers are freed from the lattice, but not enough to bring the channel into strong inversion. Thus, in the sub-threshold region, when V_{DS} is applied a small amount of current may flow. In the linear region 606 where strong inversion occurs, the current between source and drain (I_{DS}) is approximately linearly related to V_{DS}. During strong inversion operation of a PMOS enhancement mode device, for example, a negative V_{GS} bias (where |V_{GS}|>|V_{T}|) can be applied, thereby attracting positively charged holes and forming a channel of positive carriers in the channel region. While this channel is present, a drain-source voltage (V_{DS}) can be applied, thereby sweeping the positively charged holes along the fin's length L and causing current to flow. Similarly, a positive V_{GS} bias could be used in an NMOS enhancement mode device to form a negative channel, after which a suitable V_{DS} could be applied.

By comparison, accumulation mode devices typically have one type of dopant in the source/drain regions (e.g., 216/218) and the same or similar type of dopant in the channel region (e.g., 212). For example, FIG. 7A shows an accumulation mode PMOS device where the majority carriers are positively charged holes, and the source/channel/drain dopant scheme is P+/P−/P+. By comparison, FIG. 7B shows an accumulation mode NMOS device where the majority carriers are negatively charged electrons, where the source/channel/drain dopant scheme is N+/N−/N+. Because there are no p-n junctions to impede current flow, accumulation mode devices are relatively easy to turn on. For example, in a PMOS accumulation mode MuGFET, if even a slight negative V_{GS} is applied, positive holes can accumulate in the channel region and drift or diffuse between source and drain. To effectively turn the PMOS accumulation mode MuGFET off, a positive V_{GS} is typically applied, thereby repelling the majority carriers (positively charged holes) from the channel region of the fin. By asserting the gate electrode, a user cuts off (fully depletes) charged carriers from the channel region, thereby stopping the flow of current that could otherwise flow between source and drain. Similarly, a negative V_{GS} could be used to turn-off an NMOS accumulation mode MuGFET.

In digital applications where a MuGFET represents either a one-state or a zero-state, good noise margins and fast state transitions are typically desired. A high V_{T} (narrow MuGFET) may help facilitate good noise margins by increasing the voltage margin between the one-state and the zero-state. Further, because the digital devices often switch quickly and do not typically drive a large current, a short channel MuGFET may also be appropriate for digital applications. Thus, FIG. 3A's MuGFET 200 could be used in a digital manner, because it has a relatively narrow width W₁ (high V_{T}), which could facilitate good noise margins, and because it is has a relatively short gate length L₁, which would allow it to switch quickly due to low capacitance. In other various short channel embodiments to control the short channel effects, the fin width W₁ should be less than one half of the gate length L₁.

Conversely, in analog applications where a MuGFET represents a continuum of a near infinite number of states, precise matching between MuGFETs and significant drive current may be required. To this end, a low V_{T} (wide MuGFET) may facilitate good matching. In addition, because analog device may need significant drive current, a long channel MuGFET with a low V_{T} may better source the current needed for these drive currents—due in part because more overdrive voltage (V_{DD}-V_{T}) can be achieved. Thus, FIG. 4A's MuGFET 300 could be used in an analog manner, because it has a relatively wide width W₂ (low V_{T}), which could facilitate good matching, and because it has a relatively long gate length L₂, which would provide it with larger drive current. In other various long channel embodiments, to control the short channel effects, the fin width W₂ should be less than one half of the gate length L₂; as long as the fin width W₂ is less than 1.5 times the fin height h. When the fin width W₂ is greater than 1.5 times the fin height, the device may deviate from MuGFET operational mode and becomes more like a fully depleted planar MOSFET.

In theory, in one embodiment where the first gate electrode layer is a mid-gap metal, the low end of V_{T} is approximately equal to φ_{f}. This is expressed by the following V_{T} equation:

$${V}_{T} = {Φ}_{MS} + 2 {φ}_{f} - \frac{{Q}_{ox}}{{C}_{ox}} - \frac{{Q}_{ch}}{{C}_{ox}} + {V}_{inv}$$

where Φₘₛ is the difference in the work function between the first gate electrode layer and the semiconductor substrate; φ_{f} is the energy difference between the doped semiconductor in the channel region and the undoped intrinsic semiconductor Fermi level; Cₒₓ is the gate capacitance; Qₒₓ is the charge in the gate dielectric layer; Q_{ch} is the depletion charge in the channel region controlled by the gate electrode; and Vᵢₙᵥ is an additional gate voltage required beyond strong inversion 2φ_{f} as a result of thin fins (Vᵢₙᵥ tends to decrease as fins become wider, and in one embodiment Vᵢₙᵥ is approximately zero for fins having a width more than 50 nm). For a p-type substrate, φ_{f}>0, while for an n-type substrate φ_{f}<0, and the magnitude of φ_{f} equals kT/q*In(Nₐ/nᵢ), where Nₐ is the doping concentration in the channel and nᵢ is the intrinsic carrier concentration for the semiconductor material. If the work function of the first gate electrode layer is close to mid-gap, then Φₘₛ˜0V. Accordingly, in one embodiment for example, the silicon could have a doping concentration of 1E15/cm³, φ_{f}˜0.3V and Q_{ch}/Cₒₓ˜0V. Since Qₒₓ/Cₒₓ˜0V, the long channel V_{T}=Φₘₛ+2φ_{f}, and for a mid-gap metal gate we expect that V_{T}=φ_{f}.

Although one type of MuGFET was illustrated and described above where multiple gate surfaces may be controlled by a single gate electrode, other types of MuGFETs could also be used. For example, in another type of MuGFET (called a multiple independent gate field effect transistor or MIGFET), multiple gates are controlled by multiple independent gate electrodes. The invention is applicable to gate-all-around (GAA) transistors and other various types of multi-gate transistors.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. An integrated circuit comprising:
a first multi-gate transistor having a first fin width and a first threshold voltage; and
a second multi-gate transistor having a second fin width that is greater than the first width and having a second threshold voltage that is less than the first threshold voltage.

2. The circuit of claim 1, where a first gate length between a source and drain of the first multi-gate transistor is shorter than a second gate length between a source and drain of the second multi-gate transistor.

3. The circuit of claim 2, where the second gate length is at least approximately three times the first gate length.

4. The circuit of claim 1, where at least one of the multi-gate transistors operates in accumulation mode.

5. The circuit of claim 1, where at least one of the multi-gate transistors operates in depletion mode.

6. The circuit of claim 1, where all of the multi-gate transistors operate in accumulation mode or depletion mode.

7. The circuit of claim 1, where the second multi-gate transistor is configured to represent a continuum of analog states.

8. The circuit of claim 7, where the first multi-gate transistor is configured to represent either a one-state or a zero state.

9. The circuit of claim 1, where the difference between the first and second voltage thresholds is a function of the difference between the first and second fin widths.

10. An integrated circuit comprising:
a first multi-gate transistor having a first voltage threshold, the first multi-gate transistor comprising: a first fin having a first width; a first gate electrode having a first gate length that straddles the first fin approximately along the first width; and a first source and first drain separated from one another by approximately the first gate length; and
a second multi-gate transistor having a second voltage threshold that is less than the first voltage threshold, the second multi-gate transistor comprising: a second fin having a second width that is greater than the first width; a second gate electrode having a second gate length that straddles the second fin approximately along the second width; and a second source and second drain separated from one another by approximately the second gate length.

11. The integrated circuit of claim 10, where the first gate length is less than the second gate length.

12. The integrated circuit of claim 10, where the first multi-gate transistor is configured to be used in an analog manner and the second multi-gate transistor is configured to be used in a digital manner.

13. The integrated circuit of claim 10, where the first and second gate electrodes comprise: a metal layer and a polysilicon layer.

14. The integrated circuit of claim 13, where the metal layer is the same material for the first and second gate electrodes and comprises a mid-gap metal.

15. A method of providing an integrated circuit, comprising:
providing respective multiple voltage thresholds for a plurality of multi-gate transistors by varying respective fin widths of the multi-gate transistors.

16. The method of claim 15, further comprising: providing the multi-gate transistors with gates that have a single work function that is common to the gates.

17. The method of claim 15, where one of the multi-gate transistors has a gate length that is at least three times greater than a gate length of another of the multi-gate transistors.

18. The method of claim 18, where the one multi-gate transistor has a fin width that is greater than the gate length of the one multi-gate transistor.

19. The method of claim 18, where the one multi-gate transistor has a fin width that is at least double the gate length of the one multi-gate transistor.

20. The method of claim 19, where the one multi-gate transistor is configured to be used in an analog manner and the another multi-gate transistor is configured to be used in a digital manner.
